(19) United States
(12) Patent Application Publication
(10) Pub. No.: US 2023/0396034 A1
(43) Pub. Date: Dec. 7, 2023

(54) SERS SUBSTRATES MADE FROM FLEXIBLE POLYMER FILM AND METHOD OF MAKING SAME

(71) Applicant: Magued Boshra NASR, Newton, MA (US)

(72) Inventor: Magued Boshra NASR, Newton, MA (US)

(21) Appl. No.: 18/328,649

(22) Filed: Jun. 2, 2023

Related U.S. Application Data
(60) Provisional application No. 63/348,155, filed on Jun. 2, 2022.

(51) Int. Cl. H01S 3/30; C23C 14/20

(52) U.S. Cl. CPC H01S 3/30; C23C 14/20; C23C 14/24

(57) ABSTRACT

A method for manufacturing a SERS substrate according to the present invention includes providing a flexible polymer film on a first roller, where one side of the film has a base portion and nanopillars protruding from a top surface of the base portion. The film may be passed through a metal evaporation apparatus to a second roller and collected at the second roller. While the film passes through the metal evaporation apparatus, one or more metal may be evaporated to form metal pillar-heads at distal ends of corresponding nanopillars. Preferred SERS substrates have metal pillar-heads having an expected diameter to provide a LSPR wavelength for a corresponding optical excitation source and to define a SERS hot spot at a gap having an expected separation distance between adjacent metal pillar-heads.

### CROSS-REFERENCE TO RELATED APPLICATIONS

This application claims priority under 35 U.S.C. § 119(e) from U.S. provisional patent application Ser. No. 63/348,155, filed on Jun. 2, 2022, the disclosure of which is incorporated herein in its entirety by reference.

### FIELD OF THE INVENTION

The present invention generally relates to nanofabrication technology, and more particularly, surface enhanced Raman scattering (SERS) substrates and methods of manufacturing the same.

### BACKGROUND

SERS spectroscopy, first discovered in 1974, is a technique that greatly enhances the molecular Raman signal thereby permitting the detection of various analytes at very low concentrations reaching the limit of a single-molecule detection. See Fleischman, M., Hendra, P. J. and McQuillan, A. J., Raman spectra of pyridine adsorbed at a silver electrode, 1974, Chem. Phys. Lett., Vol. 26, pp. 163-166. It has many well-known uses including the detection of food additives or contaminants such as melamine in milk and the identifications of various drugs such as heroin and cocaine. See Mosier-Boss, Pamela A., Review of SERS Substrates for Chemical Sensing, 2017, Nanomaterials, Vol. 7. 142. It is also employed in forensic science, pharmaceutical manufacturing, and the early detection of various diseases. The signal enhancement is chiefly due to the optical excitation of collective electron oscillations, known as localized surface plasmons (LSP), in the nanosized metal structures of a SERS substrate by an incident laser. This LSP is strongest when the wavelength of the employed laser matches its resonant wavelength. The LSP resonance (LSPR) wavelength is longer when the dimensions of the metal structures are larger. The excitation of LSPR ultimately results in orders of magnitude enhancement of the emitted Raman signal from the molecule under study with the highest enhancement occurring when a molecule is situated at the so-called “hot spots.” Hot spot areas are formed in the gap between adjacent nanosized metal structures that are very close to each other, e.g., spaced by a few nanometers.

In general, two broad classes of the nanosized metal structures are employed in a SERS substrate: (1) metallic nano particles that are in a colloidal solution and (2) metallic nanosized structures, or a roughened metal, that are placed on the surface of the SERS substrate. For the second category, multiple geometries and fabrication processes that share the goal of keeping the nanosized structures in close vicinity have been suggested resulting in a variety of commercially-available SERS substrate.

For example, as described in Michael Stenbxk Schmidt, Jorg Hubner, and Anja Boisen, Large Area Fabrication of Leaning Silicon Nanopillars for Surface Enhanced Raman Spectroscopy, Advanced Optical Materials, 2012, 24, 11-18 (“Schmidt”), a silicon-based SERS substrate that has the top of nanosized silicon pillars coated with silver has been manufactured from a silicon wafer. A cross section diagram of said silicon-based SERS substrate is depicted in FIG. 1. To use these SERS substrates, hot spots are created between the adjacent silver lumps by causing them to lean towards each other to shorten the distance between pillars and their silver lumps. This is performed by applying drops of a volatile solvent, such as ethanol, on the surface of the SERS substrate and allowing it to evaporate. The resulting surface tension causes the pillars to lean towards each other so that they get sufficiently close to thereby form hot spots in between the adjacent leaning pillars.

The fabrication of this SERS substrate follows the steps that are illustrated in FIGS. 2A and 2B. As shown in FIG. 2A, first a blank silicon wafer is loaded into an inductively coupled plasma chamber whereat a collection of reactive species is accelerated towards the silicon wafer for a preset period of time. As a result, nanosized silicon pillars that protrude from the silicon substrate are created, as shown in FIG. 2B. This reactive-ion etching step is maskless, i.e., it does not require the use of a lithographically defined mask. Following the etching step, the substrate is loaded inside a metal evaporation chamber whereat a metal such as silver is deposited to the silicon wafer. After the metal evaporation step, the SERS substrate's structure, with the top of nanosized silicon pillars partially coated with silver, is achieved, as previously shown in FIG. 1.

In a typical Raman spectroscopy measurement, a laser light source excites the molecule under consideration and the light reradiated by the molecule is collected and analyzed using a spectrometer. At a hot spot, the electric field of the excitation laser (E_{exc}) is localized and magnified. Within the generally accepted zero Stokes shift limit approximation, the enhancement of the Raman signal due to the use of a SERS substrate, G_{SERS}, is equal to the ratio of the magnitudes of the localized electric field (E_{loc}) to that of the incident laser light (E_{exc}) raised to the power of four, i.e. G_{SERS}=|E_{loc}/E_{exc}|⁴, with the highest value attained at hot spots having the smallest gaps. This holds true for as long as the gaps are not smaller than a lower limit of about 1 nanometer. Extremely narrow gaps between adjacent metal structures can be formed via sophisticated fabrication techniques such as ebeam lithography but at a cost that is prohibitive to mass production. A successful SERS fabrication method should therefore produce hot spots with narrow gaps at a low production cost.

The fabrication of the silicon-based SERS substrates approaches this requirement by first fabricating the silicon pillars relatively far apart and coating them with metal, in a relatively cheap fashion as no lithographically defined mask is required, and subsequently creating hot spots by making the pillars lean towards each other. This is accomplished by applying a drop of a solvent, that may have the analyte dissolved in it, to the SERS substrate, as shown in FIG. 2C. As the solvent drop evaporates, the surface tension forces the silicon pillars to lean towards each other as shown in FIG. 2D, thereby creating the hot spots in between the metal lumps as they lean towards each other. If, as the pillars lean, molecules of an analyte are adsorbed to the metal, the molecules would 1) prohibit the metal lumps from coming in full contact and 2) be situated at a hot spot.

However, this fabrication method suffers from drawbacks. First, for example, the etching of a silicon wafer in a reactive-ion etching tool is rather costly due to the elevated cost of silicon wafers and to the time that is required to run the core etching step in addition to the necessary additional steps. The following are examples of additional steps: pumping the load lock to vacuum, transferring the substrate into the reactor, flowing the etching gases and stabilizing their flow and pressure, igniting the plasma, purging the chamber from the reactive gases after completion of the main etching step, transporting the wafer into the load lock and finally venting the load lock before the etched wafer can be retrieved. Second, the fabrication method does not accommodate materials that cannot withstand the high temperature of the reactive plasma. Third, the number of SERS substrates that can be produced from a single wafer is rather limited. This is the case as the largest area of mass-produced silicon wafers is currently limited to that of a twelve-inch diameter circle. In short, the SERS substrate production technique of Schmidt is not inherently suitable for mass production.

### SUMMARY

The preferred embodiments of the invention are directed at improved SERS substrates made from polymer film and methods of making same. In some embodiments, a process for manufacturing may include providing a flexible polymer film on a first roller, where one side of the film has a base portion and nanopillars protruding from a top surface of the base portion. The film may be passed through a metal evaporation apparatus to a second roller and collected at the second roller. While the film passes through the metal evaporation apparatus, one or more metal may be evaporated to form metal pillar-heads at distal ends of corresponding nanopillars. In some of the embodiments, the nanopillars may be arranged in a moth-eye pattern. Further, in some of those embodiments, the polymer film may be MOSMITE, which has nanopillars on one side arranged in a moth-eye pattern. In some embodiments, the polymer film may have the size of at least 100 mm wide by 20 m long.

In some embodiments, the manufacturing process may further include coating the formed metal pillar-heads with an anti-oxidation layer. In some embodiments, the manufacturing process may also include depositing an adhesive layer on top of the nanopillars before the metal pillar-heads are formed. In some embodiments, the metal evaporation technique used in the manufacturing process may be e-beam evaporation or thermal evaporation.

In some embodiments, the manufacturing process may further include separating the polymer film at a sufficient distance from a metal evaporation source within the metal evaporation apparatus such that the evaporated metal sufficiently cools before being deposited on to the film and its nanopillars, thereby mitigating melting of the polymer nanopillars. In some embodiments, the process may further include controlling the speed of the polymer film passing through the evaporation apparatus such that a given portion of the film passes through the metal evaporation apparatus sufficiently quickly, mitigating the effects of heat from the metal evaporation source on the polymer film. In some embodiments, the process may also include subjecting the polymer film to at least one other subsequent metal evaporation step so that metal pillar-heads are formed from multiple evaporation steps.

In some embodiments, a SERS substrate apparatus is provided. The SERS substrate may include a base portion and nanopillars protruding from a top surface of the base portion. The nanopillars may have an expected height and an expected inter-pillar separation distance relative to adjacent nanopillars. The base and the nanopillars may be a polymer. The SERS substrate may also include metal pillar-heads formed at distal ends of corresponding nanopillars where the sides of the nanopillars are substantially devoid of metal. Some of the metal pillar-heads may have an expected diameter to provide a localized surface plasmon resonance (LSPR) wavelength for a corresponding optical excitation source. Some of the metal pillar-heads may define a SERS hot spot at a gap that may be of an expected separation distance between adjacent metal pillar-heads. In some of the embodiments, the nanopillars may be arranged in a moth-eye pattern. Further, in some of those embodiments, the polymer film may be MOSMITE.

In some embodiments, the SERS substrate may have metal pillar-heads of the expected size providing the LSPR wavelength for one or more of 406 nm, 532 nm, 632.8 nm, or 785 nm standard lasers. In some embodiments, the SERS substrate may have some of the nanopillars and corresponding metal pillar-heads forming doublets in which two metal pillar-heads merge. The doublets that are larger in size than single metal pillar-heads may provide a longer LSPR wavelength than single metal pillar-heads. In some embodiments, the metal pillar-heads may be coated with an anti-oxidation layer. The metal pillar-heads, in some embodiments, may be made of one or more of silver, gold, aluminum, copper, platinum, or transparent conductive oxide. In some embodiments, the expected separation distance between adjacent metal pillar-heads of the SERS substrates may be 50 nanometers or less.

In some embodiments, the metal pillar-heads of SERS substrates may be non-conformal to the nanopillars. Also, in some embodiments, the distal ends of the nanopillars may be substantially flat.

### BRIEF DESCRIPTION OF THE DRAWINGS

FIG. 1 is a cross-sectional view of a prior art silicon-based SERS substrate.

FIGS. 2A-D are cross-sectional views that illustrate prior art fabrication and utilization steps of the silicon-based SERS substrate shown in FIG. 1.

FIGS. 3A and 3B are cross-sectional views of SERS substrates according to preferred embodiments of the present invention.

FIGS. 4A and 4B are scanning-electron microscope (SEM) images of the SERS substrate nanopillars and metal pillar-heads according to an embodiment of the present invention.

FIG. 5 is a cross-sectional view of nanopillars and their pillar-heads according to an embodiment of the present invention.

FIGS. 6A-C are cross-sectional views that illustrates the fabrication steps of the SERS substrate according to an embodiment of the present invention.

FIG. 7 is a schematic view of an exemplary method for fabricating an embodiment of the invention using a roll-to-roll apparatus.

FIGS. 8A-D are logic flow diagrams that illustrate methods for manufacturing SERS substrates according to embodiments of the present invention.

FIG. 9A depicts comparisons between measured Raman spectra, with the analyte deposited onto a SERS substrate according to a preferred embodiment of the current invention (solid-line) and with the analyte deposited on a flat silver substrate (dashed-line). FIG. 9B depicts the extinction spectrum of the SERS substrate according to an embodiment of the current invention.

### DETAILED DESCRIPTION

Preferred embodiments of the invention provide SERS substrates that have significantly reduced manufacturing costs. Preferred embodiments use lower cost materials and lower cost manufacturing steps. In addition, the apparatus is amendable to higher scale manufacturing approaches, for example, including roll-to-roll manufacturing steps utilizing flexible polymeric films having nanopillars. Preferred embodiments of the invention may utilize commercially-available anti-reflective films.

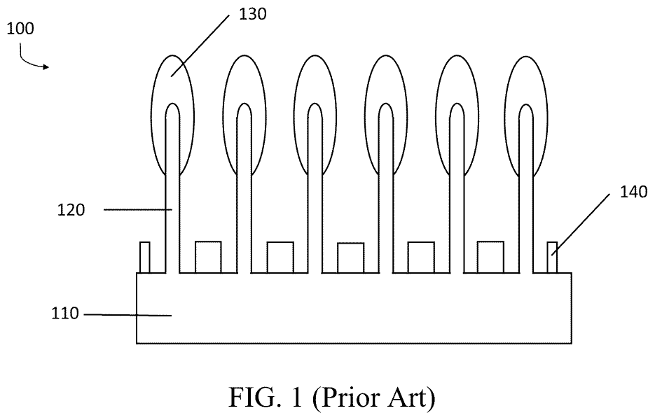

FIG. 1 is a cross sectional diagram of a prior art silicon-based SERS substrate 100. It includes a silicon wafer substrate 110, nanosized silicon pillars 120 that protrude from the silicon substrate 110, and metal lumps 130 that coat and surround the tips of the silicon nanopillars 120. . The substrate also includes metal residue 140 left on the substrate 110 in between the nanopillars 120 as a consequence of the metallization step to form lumps 130. The silicon substrate 110 is a die formed from a commercially available silicon disc that can be purchased with a diameter that ranges between 1 to 12 inches. The protruding nanopillars 120 are of the same crystalline silicon material as that of the substrate 110 and have a height that ranges between 30 to 1600 nanometers. The metal lumps 130 can be fabricated by the evaporation of metals such as silver, gold, aluminum or copper.

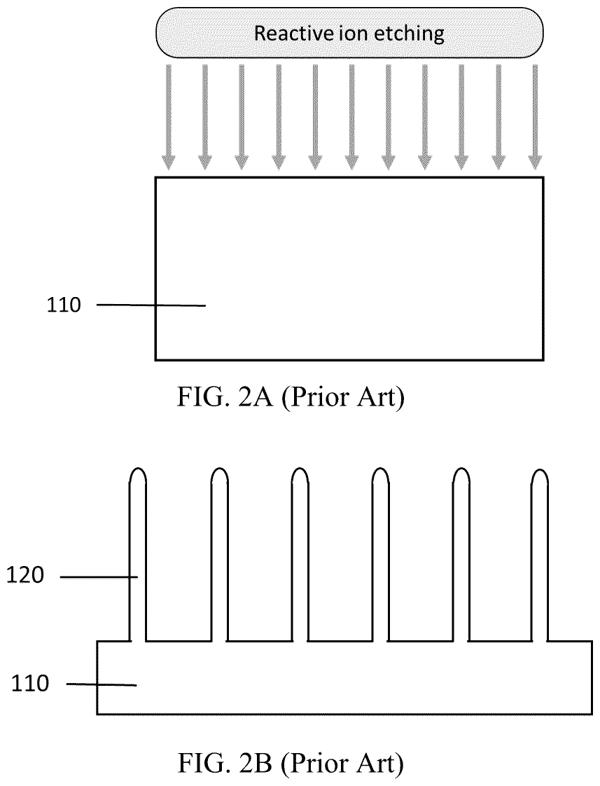

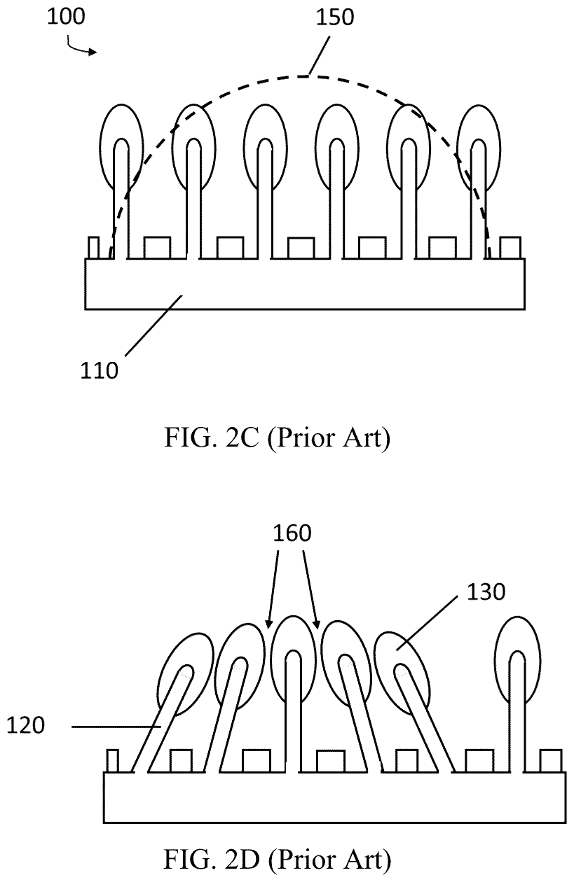

FIGS. 2A through 2D are cross-sectional views that illustrate prior art fabrication and utilization steps of the silicon-based SERS substrate 100 depicted in FIG. 1. FIG. 2A shows a maskless reactive ion etching step performed on the silicon substrate 110. In FIG. 2B, the ion etching forms nanosized silicon pillars 120 to protrude from the silicon substrate 110. This intermediate structure is subsequently subjected to a metal evaporation step, using a suitable metal such as silver. For example, the metal may be deposited by electron beam or thermal evaporation onto the silicon substrate 110 and the silicon nanopillars 120, forming the final structure of the SERS substrate 100 as depicted in FIG. 1. To use the SERS substrate of FIG. 1, the nanosized silicon pillars 120 are made to lean towards each other by subsequently adding a solvent drop 150 onto the SERS substrate 100 as shown in FIG. 2C and allowing it to evaporate. The surface tension causes the nanosized pillars 120 to lean towards each other thereby forcing the metal lumps 130 to come in sufficiently close proximity. If the molecules of an analyte are present at the metal lumps 130, such as when they are dissolved in the evaporating solvent, they will reside in the gaps 160, forming hot spots that are created between the leaning metal lumps 130 as shown in FIG. 2D; this will prevent the metal lumps 130 from directly touching each other and will enhance the Raman signal from the molecules.

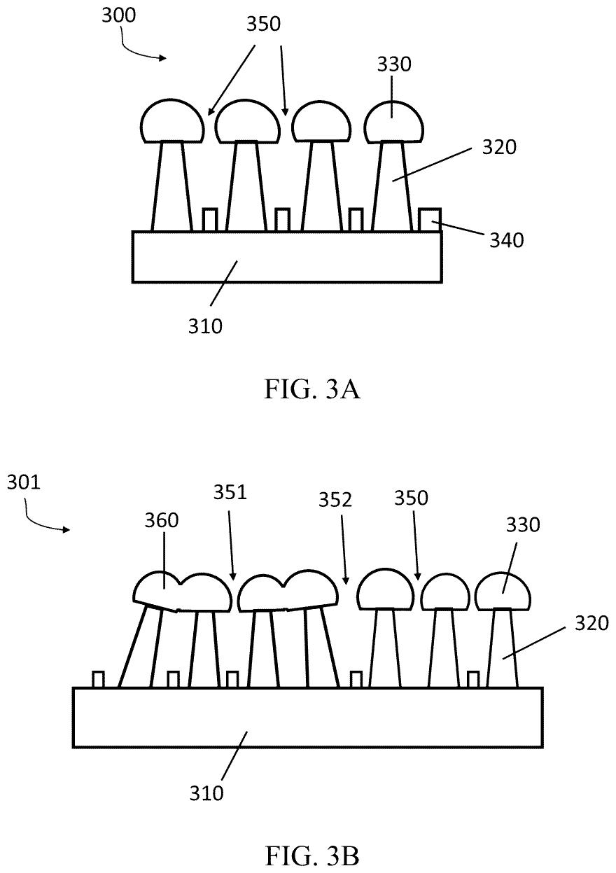

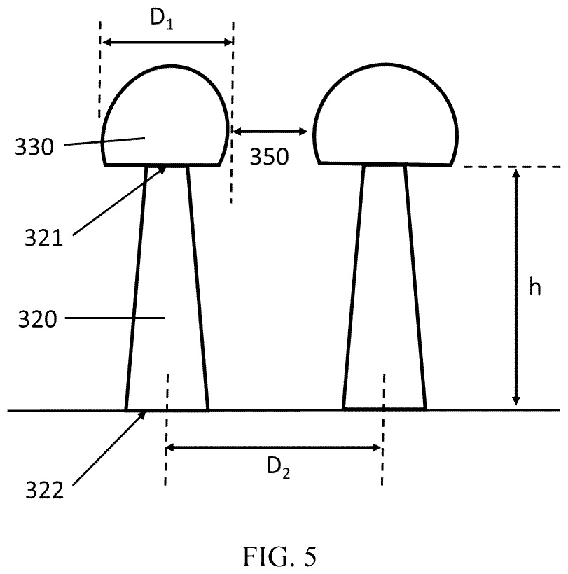

FIG. 3A is a cross-sectional diagram of a SERS substrate 300 according to a preferred embodiment of the current invention. It comprises a flexible, polymer substrate 310, nanosized pillars 320, metal pillar-heads 330 formed at a distal end of the nanopillars 320 with some metal residue 340 on the substrate 310 between the nanopillars 320. In this embodiment, hot spots are formed at gaps 350 in between the adjacent metal pillar-heads 330 in close proximity. The Raman signal of a molecule that adheres to the metal pillar-heads 330 at, or in the vicinity of, the hot spots is greatly enhanced. The dimensions and the effect thereof are further explained in detail according to FIG. 5.

In another preferred embodiment, a SERS substrate 301 as shown in FIG. 3B, some of the nanopillars 320 are tilted toward each other thereby allowing the metal pillar-heads 330 to merge. The resulting doublet 360 of the metal pillar-heads behaves like a large single metal pillar-head, and hot spots can also be formed in gaps 351 between adjacent doublets and in gaps 352 between an adjacent doublets and singlet metal pillar-heads. The LSPR wavelength of the doublet 360 is longer than that of the singlet metal pillar-head 330. The inclusion of singlet and doublet metal pillar-heads within the SERS substrate 301 broadens its excitation bandwidth thereby allowing for different wavelengths for the excitation lasers to be employed.

In yet another preferred embodiment, some of the nanopillars are tilted toward each other and form multiplets of three or more metal pillar-heads 330 merged. The resulting multiplets, similarly to the doublets 360, behave like an even larger single metal pillar-head. Hot spots can also be formed in gaps between adjacent multiplets, multiplets and doublets, and multiplets and singlets. The corresponding LSPR wavelength can be even longer in this embodiment.

In an embodiment, the nanosized pillars 320 are arranged in what is known as a moth-eye pattern. Artificial, man-made, moth-eye structures mimic the general geometry of the conical protuberances found on the corneas of moths' eyes and are usually employed to minimize the reflection of light from an otherwise non patterned surface. In general, artificial moth-eye structures consist of nanosized pillars, of various cross sections, whose base rests onto the reflecting surface and whose widths tapers as they protrude away from the surface and are spaced by 100 to 200 nanometers apart. This causes the incoming light to experience a graded refractive-index region that smoothly varies from that of the surrounding medium to that of the substrate whose surface's reflection is to be reduced. This controlled and adiabatic change of the refractive index greatly reduces the reflection of light at the surface of the substrate.

The material of the flexible substrate 310 can be any of polycarbonates, polystyrene resins, polyesters, polyurethanes, acrylic resins, polyetherSulfones, polysulfones, polyetherketones, cellulose resins (such as triacetylcellulose), polyolefins, alicyclic polyolefins, polyethylene terephthalate (PET), Polypropylene (PP), Polyvinyl chloride (PVC), Polystyrene (PS), etc. The material of the nanopillars 320 can be a curable resin of good adhesion to the chosen substrate 310. Any of the radiation cured resins such as the free radical curing acrylic compounds and the cationic based curing compounds can be used for the nanopillars 320. Thermally cured resins can also be employed. Examples of the materials for the metal pillar-heads 330 include silver, gold, aluminum, platinum, copper, and mixtures thereof. In addition, transparent conducting oxides such as indium-tin oxide (ITO) or aluminum-doped zinc oxide (AZO) can also be used for the metal pillar-heads 330. In the case where transparent conducting oxides are used, their conductive nature allows them to form hot spots in between the pillar-heads that are in close proximity.

In a preferred embodiment, an ultra-thin layer of an insulator such as silicon dioxide or a noble metal such as platinum can be coated onto the metal pillar-heads 330, using the method of atomic-layer deposition, to protect the metal pillar-heads 330 from oxidizing. If the metal pillar-heads 330 are made mostly of materials resistant to oxidation such as gold, platinum or transparent conducting oxides like ITO or AZO, the additional thin layer may be omitted. On the other hand, silver, for example, is the metal that yields the highest Raman signal amplification when employed in a SERS substrate. But it oxidizes over time and shortens the shelf lifetime of the SERS substrate product. The additional thin layer can protect the metal pillar-heads 330 from rusting and help maintaining the performance of a SERS substrate. It is preferable to keep the thickness of the layer to 1 to 5 Å such that the anti-oxidation layer does not hinder the metal pillar-heads 330 from forming hot spots.

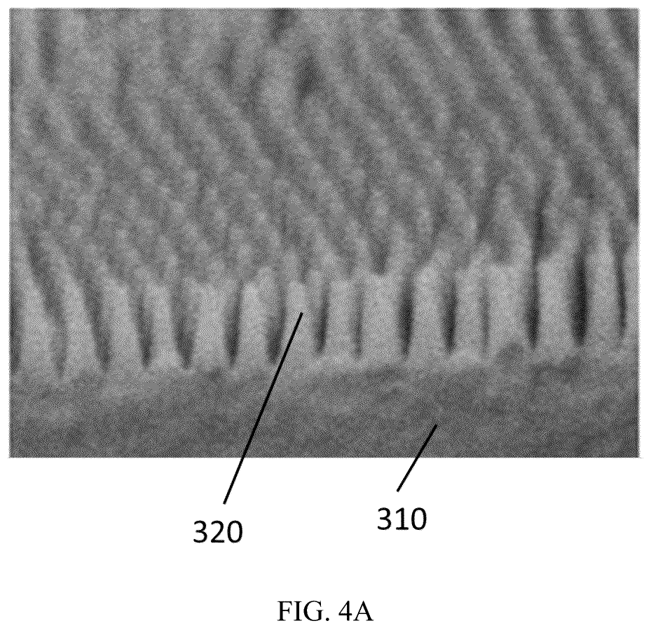

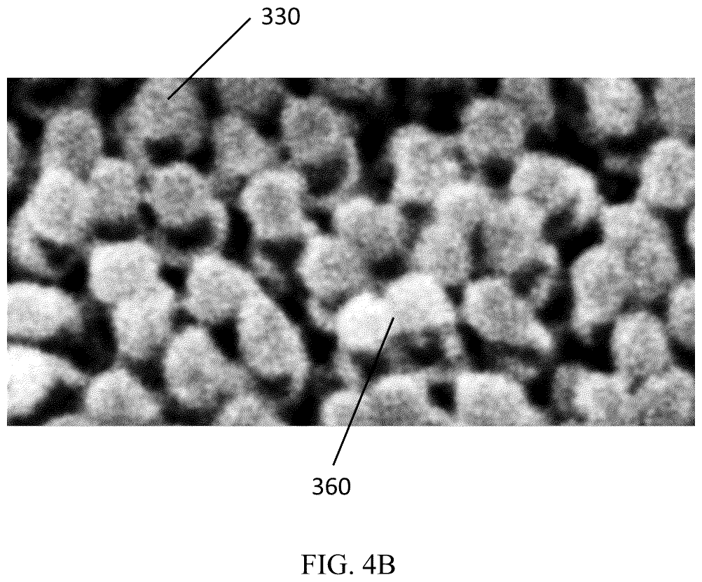

FIG. 4A is an SEM image of an exemplary polymer substrate 310 with nanopillars 320 protruding from a base portion of the substrate. In this embodiment, the nanopillars are arranged to form a moth-eye pattern. In this embodiment, the nanopillars 320 each have the shape of a truncated cone, e.g., the base is wider than the top, and the top is substantially flat. The cross section of this nanopillar is close to an isosceles trapezoid. One example of patterned polymer substrates with such shaped nanopillars that is commercially available is MOSMITE from Mitsubishi Chemical. Products like MOSMITE are used as a stick-on anti-reflection polymer film to remove the unwanted glare from glass and plastic surfaces. To operate as an efficient anti reflector the average distance between the centers of adjacent pillars 320 should be smaller than 400 nanometers, the shortest wavelength of the visible light, and preferably be in the range of 100 to 300 nanometers. Thus, one advantage of this film is that it is commercially available product manufactured in high volume at low cost. Using such a film reduces both material and manufacturing costs compared to conventional SERS manufacturing techniques.

Substrates with such structures can be used as a starting point of a preferred embodiment of the present invention. For example, a polymer substrate like MOSMITE can be subjected to metal evaporation. However, since the pillars of MOSMITE have a different shape than the silicon pillars 120 of FIG. 1, including its flat top, the metal pillar-heads 330 formed at the distal end of the pillars 320 are different. For example, the shape of the metal pillar-heads 330 may be made sufficiently large to provide LSPR wavelength between 400 to 700 nm, and also large enough compared to the inter-pillar distance to create a sufficiently small gap 350 to create a hot spot. This allows the adjacent metal pillar-heads 330 be closer to each other, and the shortened distance improves the sensitivity of hot spots formed in between the adjacent metal pillar-heads.

FIG. 4B shows a perspective view SEM image of a SERS substrate that is fabricated according to a preferred embodiment of the current invention. In FIG. 4B, the metal of the metal pillar-head 330 appears as a bright gray color while the cured resin material of the nanopillar and that of the polymer substrate appears black. The edges of the metal pillar-heads 330 are in a close proximity to each other thereby allowing hot spots to form. In addition to singlets 330, doublets 360 may also be formed as shown in FIG. 4B. The edges of the different pillars and pillar-heads that are shown in FIGS. 4A and 4B appear slightly grainy. This is an artifact of the SEM imaging tool as the sample resides on an insulating polymer substrate.

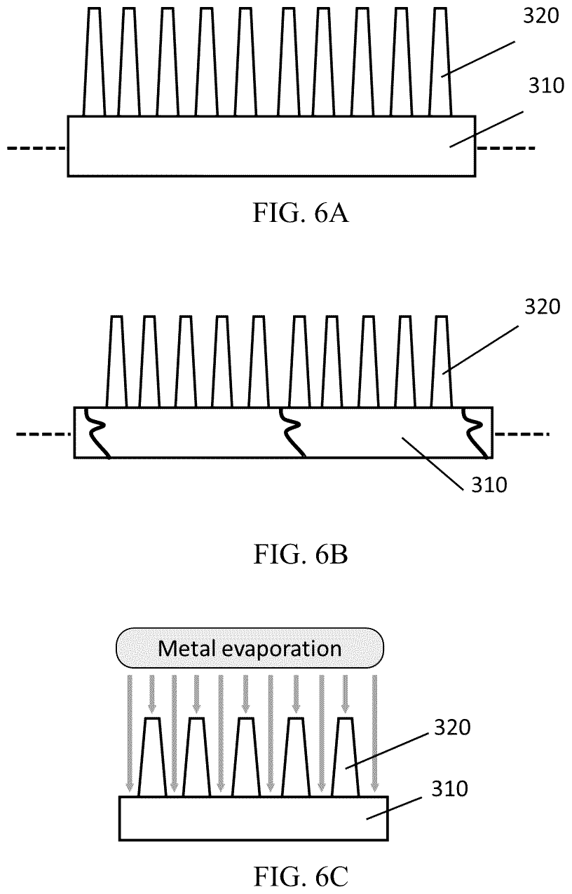

FIG. 5 is a detailed cross-sectional view of nanopillars according to an embodiment of the present invention. The three-dimensional structure of the individual nanopillars 320 can be that of a truncated cone or a truncated pyramid whereat the apex has been removed leaving behind a flat top 321 (also shown in FIG. 6A); the cross section of the nanopillar 320 is trapezoidal. The flat-topped nature of the nanopillar 320 promotes the formation of the metal pillar-head 330 during the metal evaporation. In this embodiment, the bottom 322 of the nanopillar 320 is wider than the top 321, providing stability to the nanopillar that can be made of a flexible material according to some embodiments of the current invention. In other embodiments, the bottom 322 and the top 321 can have substantially the same width. In that case, the nanopillars 320 would be more susceptible to bending.

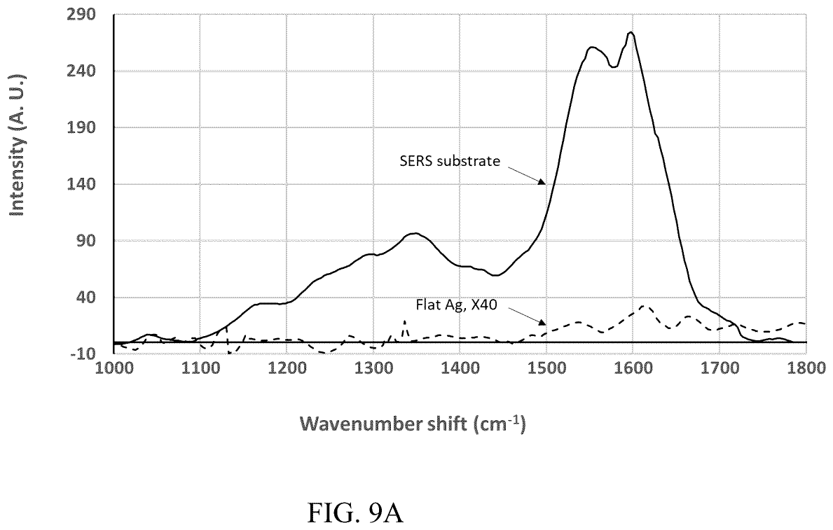

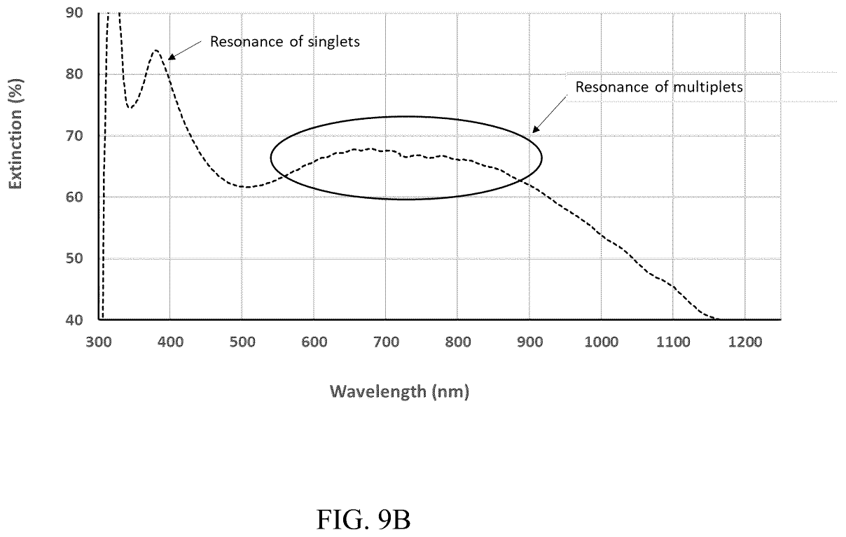

D₁, as shown in FIG. 5, is a diameter of the metal pillar-head 330, and is the widest dimension measured substantially perpendicularly to the direction of laser when the SERS substrate is put under a microscope. But in some embodiments, it may be more applicable to measure D₁ in other directions. In a preferrable embodiment, the expected D₁ of the metal pillar-heads 330 is preferably in the range of 40 to 80 nanometers. D₁ along with the material of the metal pillar-head 330 and the refractive index of the medium that surrounds the metal pillar-head dictates the LSPR wavelength and hence the wavelength of the laser that can be used for the molecules' excitation. For example, when the metal pillar-head 330 of Ag having an average D₁ 50 nanometers are employed, the resonant wavelength is around 400 nanometers, which permits the use of a standard 406-nm laser light for excitation. In addition, as the individual metal pillar-heads 330 come in contact to form doublets 360 (shown in FIG. 3B) and triplets, new LSP resonances arise at longer wavelengths. By measuring the extinction spectrum from a large area of the SERS substrate, the various LSPR wavelengths can be inferred. As shown in the extinction spectrum of FIG. 9B, singlet metal pillar-heads 330 having an average D₁≈50 nm result in a sharp resonance at 385 nm while doublets 360 as well as higher multiplets result in the appearance of a broad resonance at ≈700 nm. This broad resonance permits the use of other standard lasers at 532, 632.8 and 785 nm for the Raman excitation. A 1064 nm standard laser may also work on multiplet metal pillar-heads. The expected D₁ of metal pillar-heads 330 can be controlled during the metal evaporation process. D₁ may be made sufficiently large to establish a desired LSPR and also chosen in relation to the expected interpillar separation distance D₂ to provide a sufficiently small gap 350 to form a hot spot.

The expected distance D₂ between the centers of adjacent pillars 320 is preferably in the range of 40 to 300 nm and not more than 400 nm. At the lower end of D₂, metal pillar-heads 330 can be close enough to each other to form hot spots without the need for causing pillars to lean towards one another to create a sufficiently small gap 350. On the higher end of D₂, the leaning of the pillars 320 results in the formation of doublets 360 (as shown in FIG. 3B) and in the formation of hot spots in between singlets, in between doublets, and in between a singlet and a doublet. The average height h of the individual pillars 320 is preferably half to five times that of the dimension D₂. At the lower end of the pillar's height h, there is a lesser chance for the nanopillars to lean towards each other while at the higher end of the pillar's height h, the nanopillars 320 are more fragile. In addition, the choice of the material of the nanopillars 320 controls the mechanism of leaning.

FIGS. 6A-C are a cross-sectional views that illustrate the fabrication steps of the SERS substrates according to preferred embodiments of the current invention. The steps are: (a) start with a large sheet of a polymer substrate 310 that comprises protruding nanosized truncated conical pillars 320; (b) cut the large sheet into smaller sections that can be loaded into a metal evaporation instrument; (c) evaporate a suitable metal such as silver. Following the metal evaporation step, the SERS substrate that was detailed in FIG. 3A is obtained. In another embodiment, the SERS substrate that was detailed in FIG. 3B is obtained. As explained in accordance with FIG. 3B, some of the nanopillars 320 lean towards each other thereby allowing the metal pillar-heads 330 to merge with each other. The resulting doublet 360 behaves as a single metal with an LSPR that is distinct from that of the singlet 330, and hot spots are formed at the spacing between an adjacent pair of doublets 360, as well as at other gaps 350, 351, and 352.

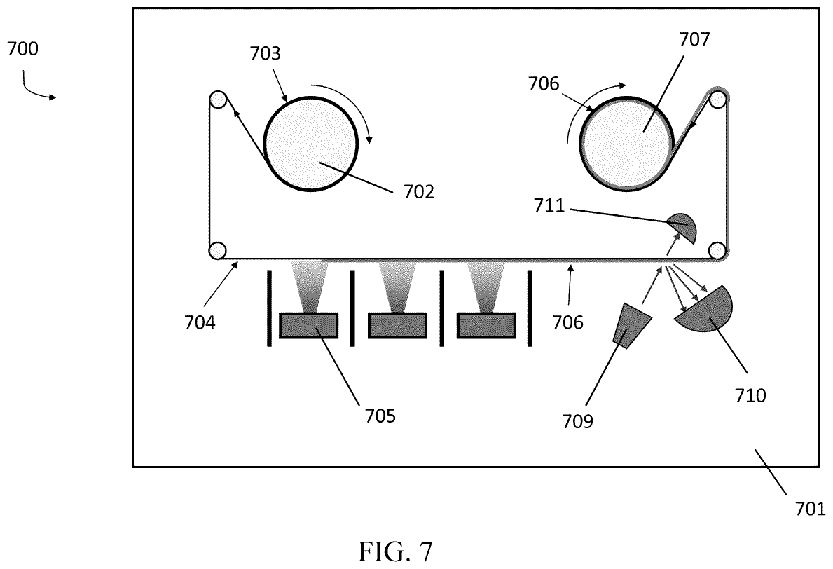

The SERS substrates 300 and 301 according to preferred embodiments of the current invention can be mass-produced using a roll-to-roll coating instrument 700 such as the one whose schematic diagram is shown in FIG. 7. This method allows mass production because a large amount of polymer film can be loaded to a roll and be fabricated into SERS substrates according to preferred embodiments. For example, a polymer film that is 600 mm wide and 100 m long can be purchased at a fraction of the cost compared to silicon wafers and be loaded. Even with smaller sized films, e.g., 100 mm wide and 20 m long, SERS substrates can be produced in much larger volume compared to silicon substrates leading to substantial efficiencies. The roll-to-roll coating instrument 700 comprises an unwinding drum 702, a winding drum 707 and successive metal deposition sources 705. In addition, a light source 709, and two light detectors 710 and 711 are used for quality control of the fabricated SERS substrate. The different components of the instrument are housed inside a vacuum chamber 701.

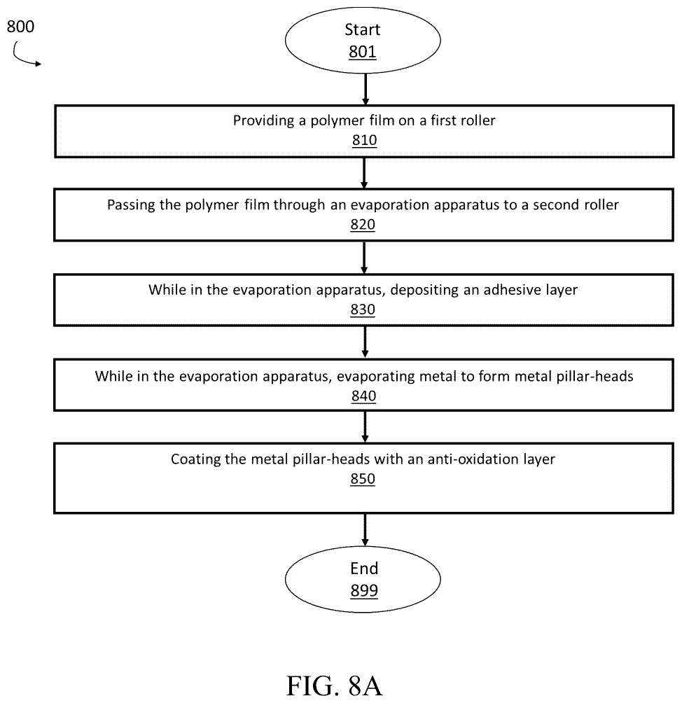

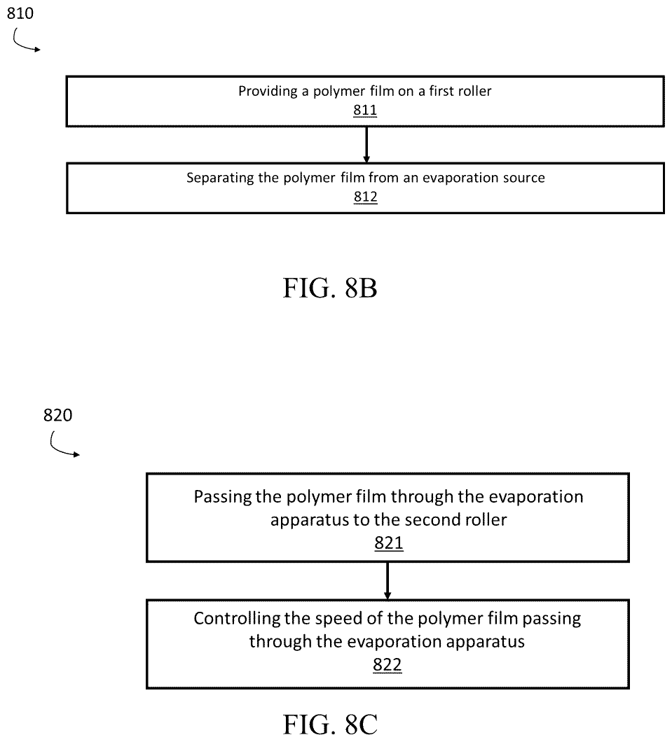

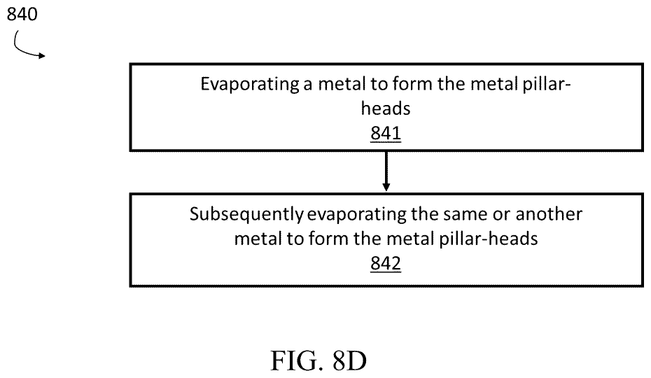

FIGS. 8A-D are flow diagrams that illustrate methods for manufacturing SERS substrates according to embodiments of the invention. For example, the production of SERS substrates using the roll-to-roll instrument 700 of FIG. 7 is explained conjointly with FIG. 8A. The roll of the flexible substrate, e.g., a polymer film, with the appropriate nano protrusions pattern 703 is loaded onto the unwinding drum 702 (step 810). The flexible substrate 703 is unwound with the surface that needs to be coated 704, i.e., the one having the nano protrusions, facing the successive metal deposition sources 705 (step 820). After passing in front of the different metal deposition sources 705, (step 840) the metal-coated flexible substrate 706 is wound onto the winding drum 707. The light source 709 and the optical detector 710 monitor the change in the reflectivity while the optical detector 711 measures the change in the transmission of the flexible substrate 706 after the metal coating. The combined parts 709, 710 and 711 are used for quality control of the SERS substrate during its production. The metal deposition sources preferably employs a metal evaporation technique that favors a deposition which is perpendicular to the surface of the polymer 704. Examples of such deposition techniques are e-beam evaporation and thermal evaporation.

In some embodiments, optional steps such as 830 and 850 can improve the quality and lifespan of SERS substrates. For example, after metal has been deposited forming metal pillar-heads (step 840), the metal pillar-heads can be further coated with an anti-oxidation layer (step 850). Coating metal pillar-heads with materials like silicon dioxide or platinum protects metal pillar-heads from rusting as discussed in detail in accordance with FIGS. 3A and B. Atomic layer deposition is one of the techniques for depositing such thin layer. Also, in some embodiments, an adhesive layer can be deposited to nanopillars of the film 703 (step 830) before the metal is deposited to the film 703 (step 840) to help form pillar-heads. In some embodiments, it can be beneficial to employ both 830 and 850 steps. The resulting SERS substrate has an adhesion layer applied in between the nanopillars and the metal pillar-heads and the metal pillar-heads are coated with an anti-oxidation layer.

In some embodiments, it could be beneficial to perform 810 as shown in FIG. 8B. For example, the film 703 can be separated from deposition sources 705 by a distance sufficient to protect the film 703 from excessive heat which might otherwise deleteriously disturb or affect the film (step 812). The separation step 812 can be done before or after the providing step 811; FIG. 8B is illustration of one example and should not be considered limiting in that aspect. Also, in some embodiments, the speed of passing the film may be adjusted so that the film 703 is not subjected to excessive heat for too long (step 822) as shown in FIG. 8C. Also, in some embodiments, the deposition of metal may employ a multi-step approach as shown in FIG. 8D so that some metal is deposited on one pass of the film (step 841) and more metal is deposited on subsequent passes of the film (step 842) within the same device (e.g., now rolling from 707 to 702, or by swapping the rolls) or by using other devices for subsequent steps (step 842).

One example of the roll-to-roll apparatus is a roll-to-roll vacuum metal coating machine, which are commercially available from companies like Plasmionique and Angstrom Engineering. These machines have been used for coating applications such as displays, thin-film and flexible photovoltaics, wearable and bendable electronics with flexible elements, such as organic displays, sensors and housings, and for various packaging solutions used in the food and pharmaceutical industries. Those machines, or modified or optimized versions thereof, may be used for preferred embodiments of the invention.

FIG. 9A depicts comparison between measured Raman spectra, with the analyte deposited onto a SERS substrate according to an embodiment of the current invention (solid-line graph) and with the analyte deposited on a flat silver substrate (dashed-line graph). The Raman signal collected from the flat silver surface is amplified via a multiplication by a factor of 40. The comparison between the two graphs clearly shows the enhanced signal that results from using the SERS substrate according to preferred embodiments of the present invention. FIG. 9B shows a graph for the measured extinction spectrum of the SERS substrate that is fabricated according to preferred embodiments of the current invention. The extinction represents the amount of light that is absorbed and scattered by the SERS substrate. The various peaks appearing in the graph represent the different localized surface plasmon resonances (LSPR) that occur in the SERS substrate. The narrow peak at ≈385 nm reflects the LSPR of singlets while the broad peak that is centered about ≈700 nm reflects the LSPR of doublets as well as other multiplets.

Although the description referenced the product MOSMITE, it can apply to other products such as the product g.moth which is commercialized by Geomatec. The use of such commercially available films promises reduced material and production costs due in part to the low cost of the films. That said, the present invention is not limited to currently commercially-available films. For example, production volume may be sufficiently large to warrant the creation of films with dimensions and properties more tailored and/or optimized for SERS substrates and which might also benefit from the roll-to-roll techniques discussed herein.

While the invention has been described in connection with one or more embodiments, it should be understood that the invention is not limited to those embodiments. The foregoing descriptions of specific embodiments of the present invention are presented for purposes of illustration and description. The embodiments are shown and described in order to best explain the principles of the invention and its practical applications, to thereby enable others skilled in the art to best utilize the invention and various embodiments with various modifications as are suited to the particular use contemplated. Also, it is to be understood that the phraseology and terminology employed herein are for the purpose of description and should not be regarded as limiting. It is intended that the scope of the invention be defined by the following claims and their equivalents.

What is claimed is:

1. A method for manufacturing a SERS substrate, comprising:
providing a flexible polymer film on a first roller, one side of the film having a base portion and a plurality of nanopillars protruding from a top surface of the base portion;
passing the polymer film through a metal evaporation apparatus to a second roller;
using the metal evaporation apparatus to evaporate metal to form a plurality of metal pillar-heads at distal ends of corresponding nanopillars.

2. The method of claim 1, wherein the nanopillars are arranged in a moth-eye pattern.

3. The method of claim 2, wherein the polymer film is MOSMITE.

4. The method of claim 1, further comprising:
coating the metal pillar-heads with an anti-oxidation layer.

5. The method of claim 1, further comprising:
before evaporating the metal, depositing an adhesive layer to the nanopillars.

6. The method of claim 1, further comprising:
sufficiently separating the polymer film from a metal evaporation source within the metal evaporation apparatus such that the evaporated metal sufficiently cools before being deposited on to the film and its nanopillars so as to mitigate melting of the nanopillars.

7. The method of claim 1, further comprising:
controlling the speed of the polymer film passing through the evaporation apparatus such that a given portion of the film passes through metal evaporation apparatus sufficiently quickly to mitigate the effects of heat from a metal evaporation source on the polymer film.

8. The method of claim 1, further comprising:
subjecting the polymer film to at least one other subsequent metal evaporation step so that the metal pillar-heads are formed from multiple evaporation steps.

9. The method of claim 1, wherein the size of the polymer film is at least 100 mm wide and 20 m long.

10. The method of claim 1, wherein the metal evaporation is one of e-beam evaporation or thermal evaporation.

11. A SERS substrate, comprising:
a base portion and a plurality of nanopillars protruding from a top surface of the base portion, the nanopillars having an expected height and an expected inter-pillar separation distance relative to adjacent nanopillars, the base portion and the nanopillars being a polymeric material; and
a plurality of metal pillar-heads formed at distal ends of corresponding nanopillars, with the sides of the nanopillars being substantially devoid of metal, at least a plurality of the metal pillar-heads having an expected diameter to provide a localized surface plasmon resonance (LSPR) wavelength for a corresponding optical excitation source and to define a SERS hot spot at a gap having an expected separation distance between adjacent metal pillar-heads.

12. The SERS substrate of claim 11, wherein the nanopillars are arranged in a moth-eye pattern.

13. The SERS substrate of claim 12, wherein the base portion and the nanopillars are a portion of MOSMITE film.

14. The SERS substrate of claim 11, wherein the expected diameter of the metal pillar-heads provide the LSPR wavelength for one or more of 406 nm, 532 nm, 632.8 nm, or 785 nm standard lasers.

15. The SERS substrate of claim 11, wherein at least some of the nanopillars and corresponding metal pillar-heads form doublets in which two metal pillar-heads merge, the doublets thereby having a larger size, merged metal pillar-heads to provide a longer LSPR wavelength.

16. The SERS substrate of claim 11, wherein the metal pillar-heads are coated with an anti-oxidation layer.

17. The SERS substrate of claim 11, wherein the metal pillar-heads are made of one or more of silver, gold, aluminum, copper, or platinum.

18. The SERS substrate of claim 11, wherein the expected separation distance is 50 nanometers or less.

19. The SERS substrate of claim 11, wherein the metal pillar-heads are non-conformal to the nanopillars.

20. The SERS substrate of claim 11, wherein the distal ends of the nanopillars are substantially flat.
